(19) United States
(12) Patent Application Publication
(10) Pub. No.: US 2025/0093774 A1
(43) Pub. Date: Mar. 20, 2025

(54) RESIST UNDER-LAYER FOR USE IN A LITHOGRAPHIC APPARATUS

(71) Applicant: ASML NETHERLANDS B.V., Veldhoven (NL)

(72) Inventor: Sander Frederik WUISTER, Eindhoven (NL)

(73) Assignee: ASML NETHERLANDS B.V., Veldhoven (NL)

(21) Appl. No.: 18/724,326

(22) PCT Filed: Dec. 20, 2022
(86) PCT No.: PCT/EP2022/087032

§ 371 Date: Jun. 26, 2024

(30) Foreign Application Priority Data
Jan. 19, 2022 (EP) 22152243.6

(51) Int. Cl. G03F 7/004; G03F 7/095; G03F 7/11; G03F 7/20; G03F 7/26

(52) U.S. Cl. CPC G03F 7/0045; G03F 7/095; G03F 7/11; G03F 7/2004; G03F 7/26

(57) ABSTRACT

A substrate arrangement for use in a lithographic apparatus, the substrate arrangement including: a resist; a photosensitive resist under-layer; and a substrate, wherein an exposure threshold of the resist under-layer is lower than an exposure threshold of the resist. The resist and the resist under-layer may be both photosensitive to EUV radiation.

### CROSS-REFERENCE TO RELATED APPLICATIONS

This application claims priority of EP application 22152243.6 which was filed on 19 Jan. 2022, and which is incorporated herein in its entirety by reference.

### FIELD

The present invention relates to the composition of the under-layer of a resist in a lithographic process, the use of such a resist under-layer in a lithographic process and the manufacture of semiconductors in a lithographic process using such a resist under-layer. The resist under-layer may be particularly appropriate for use in EUV lithography and may enable the use of increasingly large numeric apertures.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

There is a general desire to increase the numeric aperture (NA) of EUV systems.

### SUMMARY

According to a first aspect of the invention, there is provided a substrate arrangement for use in a lithographic apparatus, the substrate arrangement comprising: a resist; a photosensitive resist under-layer; and a substrate; wherein the exposure threshold of the resist under-layer is lower than the exposure threshold of the resist.

According to a second aspect of the invention, there is provided a lithographic apparatus comprising the substrate arrangement according to the first aspect.

According to a third aspect of the invention, there is provided the use of a substrate arrangement according to the first aspect in a lithographic process.

According to a fourth aspect of the invention, there is provided a method of manufacturing a substrate arrangement, the method comprising: coating the surface of a substrate with a photosensitive resist under-layer; and providing a resist on the photosensitive resist under-layer; wherein the exposure threshold of the resist under-layer is lower than the exposure threshold of the resist.

According to a fifth aspect of the invention, there is provided a method comprising: projecting a patterned beam of radiation onto a substrate arrangement according to the first aspect in an exposure process; and performing a development process on the substrate arrangement.

According to a sixth aspect of the invention, there is provided a method comprising using the method according to the fifth aspect in the manufacture of semiconductors by a lithographic apparatus.

According to a seventh aspect of the invention, there is provided a device manufactured according to the method of the sixth aspect.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIGS. 2A to 2C depict the formation of an opening in a layer of resist that is on the surface of a substrate according to known techniques; and

FIGS. 3A to 3C depict the formation of an opening in a layer of resist that is on the surface of a substrate according to embodiments.

### DETAILED DESCRIPTION

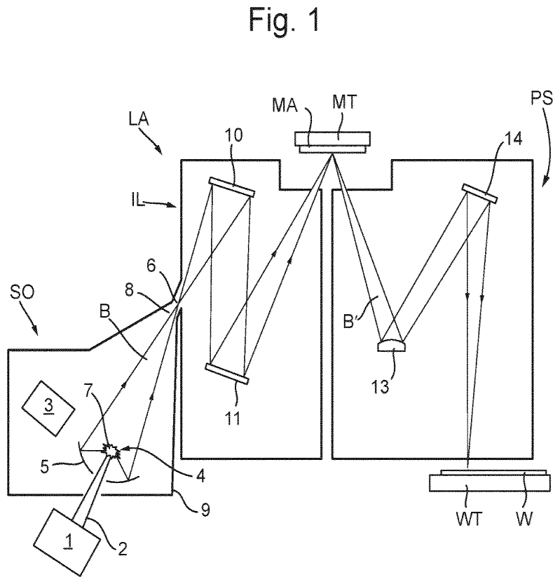

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation.

The process of manufacturing semiconductors comprises coating a surface of the substrate with a resist. An exposure process may then be performed in which the surface coated by the resist is irradiated by the patterned EUV radiation beam. Photons in the patterned EUV radiation beam react with the resist to induce a change in the irradiated parts of the resist. A development process may then be performed in which either only the changed parts of the resist, or only the unchanged parts of the resist, are removed so that the surface of the substrate is coated with resist with a pattern that is dependent on the pattern of the EUV radiation beam. Further processes may then be performed to manufacture semiconductors in dependence on the pattern of the resist on the surface of the substrate.

A known resist suitable for use with lithography is a chemically amplified resist (CAR) and may be based on polymers. Upon exposure to electromagnetic radiation, the polymers in the CAR absorb photons and secondary electrons may be generated. The generation of secondary electrons in the resist is how a high-energy photon loses most of its energy. The secondary electrons in the resist diffuse and may generate further secondary electrons with lower energies until the energy of the secondary electrons is lower than that required to break bonds in the CAR. The electrons generated excite photo-acid generators (PAGs) which subsequently decompose and can catalyse a de-blocking reaction that occurs on the polymer. This leads to a change in solubility of the CAR.

Alternative resists for use in lithography, in particular EUV lithography, that comprise metal oxide nanoclusters have been investigated to try to address the issues with CARs. These alternative resists comprise metal oxide nanoparticles or nanoclusters which are prevented from clustering together by a ligand shell. Upon EUV exposure, photons are absorbed by the nanoparticles or nanoclusters to cluster together and hence changes the solubility of the resist. The metal oxide nanoparticles have larger EUV absorption cross-sections than carbon atoms in CAR and thus there is a greater likelihood of EUV photons being absorbed. Therefore, a less intense beam requiring less power or a shorter exposure to the EUV photons is required. Furthermore, the different conversion mechanism has potentially lower chemical noise than CAR resist system.

The critical dimension, CD, of features manufactured by a lithography system is given by the Rayleigh equation as:

$$CD = \frac{{k}_{1} λ}{NA}$$

The CD is therefore directly proportional to the wavelength, A, of the electromagnetic radiation and inversely proportional to the numerical aperture, NA, of the lithographic system.

The depth of focus, DoF, of the electromagnetic radiation in a lithographic system is:

$$DoF = \frac{{k}_{1} λ}{{NA}^{2}}$$

The DoF is therefore inversely proportional to the square of the NA.

There is a general desire to decrease the CD so that smaller features may be manufactured by the lithography system. The use of an EUV system allows a smaller CD compared to longer wavelength lithographic systems. To decrease the CD further for a given wavelength, it is necessary for the NA to be increased. The NA of a EUV system may be increased by, for example, changes to the designs of the mirrors in the EUV system. The standard NA of an EUV system is about 0.33. However, it is possible for the NA of an EUV system to be increased to about, for example, 0.55.

A consequence of increasing the NA is that the DoF is decreased. When the NA of an EUV system is increased from 0.33 to 0.55, the DoF may be decreased to the extent that the variation in the image contrast per image plane becomes substantial through the depth of the resist. Furthermore, the electromagnetic radiation is absorbed in the resist and so the intensity of the electromagnetic radiation is lowest at the surface of the resist that faces the substrate W. There is therefore a lower focus latitude in the negative focus direction than in the positive focus direction.

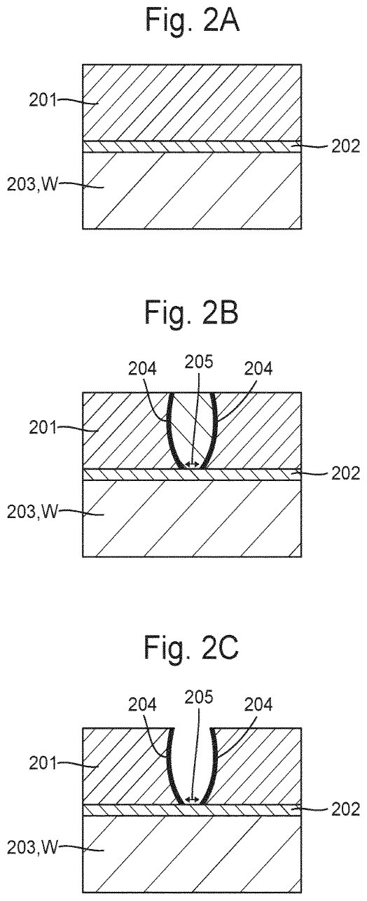

Some of the problems resulting from a reduced DoF are explained below with reference to FIGS. 2A to 2C.

FIG. 2A shows a known arrangement of a resist 201 on a substrate 203, W. There is a resist under-layer 202, that is an intermediate layer of material, provided between the layer of resist 201 and the surface of the substrate 203, W. The use of a resist under-layer may improve the securing, such as adhesion, of the resist 201 to the substrate 203, W.

FIG. 2B shows the changes in the resist 201 of FIG. 2A after an exposure process has been performed and before a development process has been performed. The exposed region of the resist 201 is approximately indicated by, and approximately bounded by, the exposure boundaries 204. The focus plane of the electromagnetic radiation is approximately at the mid-depth of the resist 201 and indicated by the maximum separation distance between the exposure boundaries 204. Due to the change of DoF through the depth of the resist 201, the separation distance 205 between the exposure boundaries 204 at the resist under-layer 202 may be substantially less than the maximum separation distance between the exposure boundaries 204.

FIG. 2C shows the resist 201 of FIG. 2B after a development process has been performed. The exposed region of the resist 201 has been removed by the development process. The separation distance 205 between the formed features at the resist under-layer 202 may be less than the minimum tolerable separation distance according to the design specification. This problem is a consequence of the low DoF and may limit the magnitude of NA that may be used.

A way of reducing the above problems caused by a low DoF is to use thinner resists 201. However, reducing the thickness of the resist 201 causes other problems. In particular, as the thickness of the resist 201 is reduced the local critical dimension uniformity (LCDU) penalty increases. For all types of resist 201, there is also a minimum thickness that the resist 201 should not be thinner than in order for the resist to be suitable for use in subsequent processes, such as etching.

Embodiments solve the above problems by providing a technique for at least partially compensating for the effects caused by the low DoF when a large NA is used in an EUV system.

Embodiments provide a new type of resist under-layer. The resist under-layer may be photosensitive so that its properties change during the exposure process. In particular, the resist under-layer may change from being hydrophobic to hydrophilic during the exposure process. During the development process, the changed resist under-layer may cause movement and/or removal of the resist that at least partially compensates the effects caused by the low DOF.

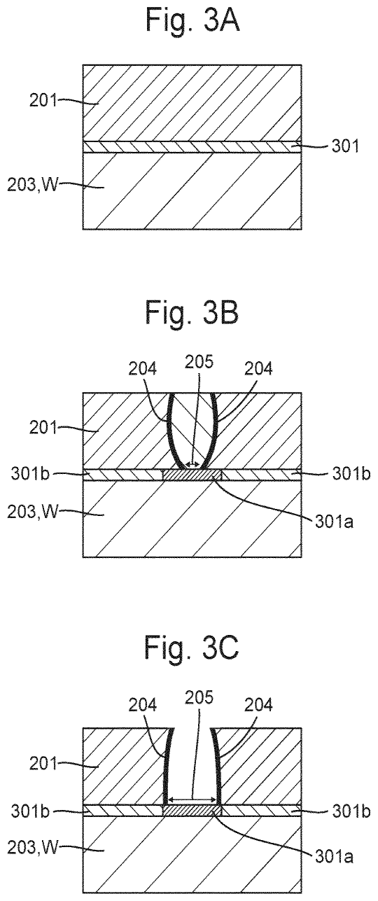

FIGS. 3A to 3C illustrate the use of the new resist under-layer 301 according to embodiments.

FIG. 3A shows the arrangement of the resist 201 on the substrate 203, W. There is a resist under-layer 301, that is an intermediate layer of material, provided between the layer of resist 201 and the surface of the substrate 203, W. The use of a resist under-layer 301 may improve the securing, such as adhesion, of the resist 201 to the substrate 203, W. The arrangement shown in FIG. 3A may only differ from the known arrangement shown in FIG. 2A by the type of material used for the resist under-layer 301.

FIG. 3B shows the changes in the resist 201 and resist under-layer 301 of FIG. 3A after an exposure process has been performed and before a development process has been performed. The exposed region of the resist is approximately indicated by, and approximately bounded by, the exposure boundaries 204. The focus plane of the electromagnetic radiation is approximately at the mid-depth of the resist 201 and indicated by the maximum separation distance between the exposure boundaries 204. Due to the change of DoF through the depth of the resist 201, the separation distance 205 between the exposure boundaries 204 at the resist under-layer 301 may be substantially less than the maximum separation distance between the exposure boundaries 204.

A first region 301a of the resist under-layer 301 has been changed by the exposure process. The resist under-layer 301 is photosensitive and a change, that may be a chemical reaction, has occurred in the first region 301a due to the illumination with photons in the exposure process. The effect of the change may be that the first region 301a of the resist under-layer 301 has different surface tension properties. For example, the surface of the first region 301a of the resist under-layer 301 may become more hydrophilic due to the exposure process. There is also a second region 301b of the resist under-layer 301 has not been illuminated in the exposure process and its properties therefore are substantially unchanged by the exposure process.

In the development process, the removal and/or movement of the resist 201 may be dependent on the surface properties of the resist under-layer 301 below the resist 201. In particular, as the hydrophilic properties of the resist under-layer 301 are increased, the removal and/or movement of the resist 201 above the resist under-layer 301 may be increased. As described above, the exposure process may cause the first region 301a of the resist under-layer 301 to be more hydrophilic than the second region 301b of the resist under-layer 301. This may substantially change the removal and/or movement of the resist 201 above the first region 301a of the resist under-layer 301 in the development process. In particular, during the development process, the development liquid that washes the exposed resist 201 away may have a surface tension that pushes parts of resist 201 outwards. The resist 201 above the first region 301a of the resist under-layer 301 may be moved more by the development liquid due to the increased hydrophilic properties of the resist under-layer 301a in the first region 301a. Parts of the resist 201 may therefore be pushed outwards towards the boundary between the first region 301a and the second region 301b of the resist under-layer 301.

FIG. 3C shows the resist 201 of FIG. 3B after a development process has been performed. The development process may remove, or move, the resist 201 that is above the first region 301a of the resist under-layer 301 outwards. The resist 201 may be moved substantially to the boundary of the first region 301a and the second region 301b. This may have the effect of making the opening in the resist 201 wider at the part that is close to the resist under-layer to thereby increase the separation distance 205 between the formed features at the resist under-layer 301. Accordingly, the use of a photosensitive resist under-layer according to embodiments may at least partially correct the effect of the reduced DoF when a large NA is used.

The resist under-layer 301 according to embodiments may be made of a number of different types of photosensitive material. A property of the photosensitive material that changes during the exposure process may be the polarity of the photosensitive material. The polarity of the photosensitive material may change by any of the magnitude of the polarity increasing, the magnitude of the polarity deceasing or the sign of the polarity changing (such as from polar to apolar). The changed polarity may increase the hydrophilic component of the surface tension of the resist under-layer.

The resist under-layer 301 according to embodiments will have an exposure threshold. The property change of the resist under-layer 301 may occur when the received energy, or intensity, from the irradiation with photons in the exposure process is above the required exposure threshold. Similarly, the resist 201 will also have an exposure threshold. The property change of the resist 201 may occur when the received energy, or intensity, from irradiation with photons in the exposure process is above the required exposure threshold.

The exposure threshold of the resist under-layer 301 may be lower than the exposure threshold of the resist 201. Accordingly, during the exposure process, the resist under-layer 301 may be irradiated with photons to, or above, the threshold level for the resist under-layer 301 even when there has been a substantial amount of absorption of the photons in the resist 201.

As shown in FIG. 3B, the exposure boundaries 204 of the resist 201 are dependent on the exposure threshold of the resist 201. However, the first region 301a is defined by the lower exposure threshold of the resist under-layer 301. Due to the different exposure thresholds, the first region 301a may have a larger footprint on the resist under-layer 301 than the region bounded by the exposure boundaries 204 at the resist under-layer 301.

A preferred implementation of the resist under-layer 301 according to embodiments is described below.

The resist under-layer 301 may comprise one or more polymers, and/or base resins, as well as a thermal initiator and PAGs. The polymers may comprises a plurality of monomeric groups with different properties. In particular, some of the monomeric groups may be cross-linkable by the thermal initiator when the resist under-layer 301 is baked. The cross-linking of the monomeric groups may reduce their solubility and may thereby prevent the removal of the resist under-layer 301 in the development process. The property of other monomeric groups may be that their polarity changes during the exposure process. Such a polarity change may make the resist under-layer 301 more hydrophilic. The monomeric groups that undergo a change in the exposure process may initially be protected. In the exposure process, the PAGs in the resist under-layer 301 may generate acids that catalyse a reaction that removes the protection from the protected monomeric groups to thereby change the polarity of the monomeric groups.

The process of forming the resist under-layer 301 may comprise spin coating the resist under-layer 301 onto the surface of the substrate 203, W according to known techniques. The resist under-layer 301 may then be baked so that the thermal initiator is activated. The thermal activation may cause some of the monomeric groups of the resist under-layer 301 to form cross-linked groups so that the resist under-layer 301 is no longer soluble in the development liquid. The monomeric groups that change in the exposure process may be substantially unchanged by the thermal activation process (i.e. baking).

The monomeric groups that change in the exposure process may initially be protected. The term ‘protected’ in this context means that each monomer in the monomeric group is apolar (i.e. not polar). The apolar property of each monomer may be, for example, due to the presence of a t-butyl group.

The PAGs in the resist under-layer 301 may be photosensitive to EUV radiation. In the exposure process, the PAGs in the resist under-layer 301 may be activated by the EUV radiation and thereby generate acids. The protected monomeric groups may then react, in a reaction catalysed by the acid, so that the monomeric groups are no longer protected and therefore do comprise polar monomers. For example, the reaction may cause the t-buty component of a monomer to be replaced with an OH component (which is polar). The change in polarity may cause the exposed region of the resist under-layer 301 to become more hydrophilic. The exposed resist 201 may also become more hydrophilic and/or change polarity in the same exposure process. In addition to exposure with EUV radiation, the exposure process may also comprise baking so that at least the resist under-layer 301 is heated.

The exposure threshold of the resist under-layer 301 and resist 201 may be dependent on their PAG concentration. In particular, the exposure threshold may decrease as the PAG concentration is increased. The exposure threshold of the resist under-layer 301 may be set at a lower level than that of the resist 201 by providing a higher PAG concentration in the resist under-layer 301 than in the resist 201.

About 5% wt to 20% wt of the resist under-layer 301 may be comprised by monomeric groups that are cross-linkable. The thermal initiator in the resist under-layer 301 is configured to cross-link the cross-linkable monomeric groups when the resist under-layer is baked. The cross-linkable constituents of the resist under-layer 301 may comprise acrylate groups, methacrylate groups and/or epoxy groups.

About 0.5% wt to 5% wt of the resist under-layer 301 may be comprised by the thermal initiator. The thermal initiator may comprise one or more of 1,1′-Azobis(cyclohexanecarbonitrile), 2,2′-Azobisisobutyronitrile (AIBN), Benzoyl peroxide2 Benzene, 2,2-Bis(tert-butylperoxy)butane, 1,1-Bis(tert-butylperoxy)cyclohexane, 2,5-Bis(tert-butylperoxy)-2,5-dimethylhexane, 2,5-Bis(tert-Butylperoxy)-2,5-dimethyl-3-hexyne, Bis(1-(tert-butylperoxy)-1-methylethyl)benzene, 1,1-Bis(tert-butylperoxy)-3,3,5-85 (dibutyl phthalate) trimethylcyclohexane, tert-Butyl hydroperoxide Benzene, tert-Butyl peracetate Benzene, tert-Butyl peroxide Benzene, tert-Butyl peroxybenzoate, tert-Butylperoxy isopropyl carbonate Cumene, Cyclohexanone peroxide, Dicumyl peroxide Benzene, Lauroyl peroxide Benzene, 2,4-Pentanedione peroxide. The thermal intiator may be any of the thermal initiators as listed in ‘Polymer Handbook’; Eds. Brandrup, J; Immergur, E. H.; Grulke, E. A., 4^{th} Edition, John Wiley, New York, 1999, II/2-69; Aldrich Catalog No. Z412473.

The substantial part of the resist under-layer 301 may be the initially protected monomeric groups. These may be cleaved, by the acids generated by the PAGs, to generate a hydrophilic substance. Suitable initially protected resist under-layer 301 constituents may include tert-butoxycarbonyl protected polyhydroxystyrene, adamanthoxyethyl protected polyhydroxystyrene, and/or t-butyl acrylate.

Alternatively, or additionally, the resist under-layer 301 according to embodiments may comprise small molecules such as ionic and non-ionic photoacid generators (PAGs). These may comprise benzyl esters, imino esters, sulfonium or iodonium based PAGs. The small molecules may be attached to inorganic surfaces or (non-soluble) organic polymers.

Alternatively, or additionally, the resist under-layer 301 according to embodiments may comprise polymers that are intrinsically photosensitive. For example, the resist under-layer may comprise polyvinylpyrrolidone (PVP) that changes polarity, such as becomes more polar, when irradiated with EUV electromagnetic radiation.

Alternatively, or additionally, the resist under-layer 301 according to embodiments may comprise inorganic materials such as thin oxides.

As described above, a main advantage of embodiments is that an adverse effect arising from the use of a low DoF is at least partially compensated for and corrected. This allows a larger NA to be used and is particularly advantageous in EUV lithography systems.

A further advantage of embodiments is that the use of a photosensitive resist under-layer 301 may allow a lower dose to be used during the exposure process than with known techniques. According to known techniques, reducing the dose during the exposure process increases the line width roughness (LWR). However, the techniques according to embodiments may change the polarity of the exposed parts of the resist under-layer 301. The change of polarity may decrease the LWR. Accordingly, for the same LWR performance, embodiments may allow a lower dose to be used.

Embodiments include the use of a resist under-layer according to the above-described embodiments in a lithographic process.

Embodiments include projecting a patterned beam of radiation onto a substrate arrangement that comprises the resist under-layer according to embodiments in an exposure process. A development process may be subsequently performed on the substrate arrangement. These process may be performed in the manufacture of semiconductors by a lithographic apparatus.

Embodiments include devices manufactured according to the method of embodiments.

Embodiments include a number of modifications and variations to the above-described techniques.

Embodiments are set out in the following numbered clauses:
1. A substrate arrangement for use in a lithographic apparatus, the substrate arrangement comprising: a resist; a photosensitive resist under-layer; and a substrate; wherein the exposure threshold of the resist under-layer is lower than the exposure threshold of the resist.
2. The substrate arrangement according to clause 1, wherein the resist and the resist under-layer are both photosensitive to EUV radiation.
3. The substrate arrangement according to clause 1 or 2, wherein the resist under-layer is configured to become more hydrophilic in response to irradiation by EUV radiation.
4. The substrate arrangement according to any preceding clause, wherein, in response to irradiation by EUV radiation, the polarity of the resist under-layer is configured to increase in magnitude, decrease in magnitude or change in sign.
5. The substrate arrangement according to any preceding clause, wherein: the resist under-layer comprises polymers, a thermal initiator and a photoacid generator (PAG); and the polymers comprise both cross-linkable groups and protected groups.
6. The substrate arrangement according to clause 5, wherein the substantial part of the resist under-layer is the protected groups.
7. The substrate arrangement according to clause 5 or 6, wherein the thermal initiator is configured to cross-link the cross-linkable groups in response to the resist under-layer being baked.
8. The substrate arrangement according to clause 7, wherein the thermal initiator comprises one or more of acrylate groups, methacrylate groups, epoxy groups, 1,1′-Azobis(cyclohexanecarbonitrile), 2,2′-Azobisisobutyronitrile (AIBN), Benzoyl peroxide2 Benzene, 2,2-Bis(tert-butylperoxy)butane, 1,1-Bis(tert-butylperoxy)cyclohexane, 2,5-Bis(tert-butylperoxy)-2,5-dimethylhexane, 2,5-Bis(tert-Butylperoxy)-2,5-dimethyl-3-hexyne, Bis(1-(tert-butylperoxy)-1-methylethyl)benzene, 1,1-Bis(tert-butylperoxy)-3,3,5-85 (dibutyl phthalate) trimethylcyclohexane, tert-Butyl hydroperoxide Benzene, tert-Butyl peracetate Benzene, tert-Butyl peroxide Benzene, tert-Butyl peroxybenzoate, tert-Butylperoxy isopropyl carbonate Cumene, Cyclohexanone peroxide, Dicumyl peroxide Benzene, and Lauroyl peroxide Benzene, 2,4-Pentanedione peroxide.
9. The substrate arrangement according to any of clauses 5 to 8, wherein the protected groups comprise one or more of tert-butoxycarbonyl protected polyhydroxystyrene, adamanthoxyethyl protected polyhydroxystyrene, and t-butyl acrylate.
10. The substrate arrangement according any of clauses 5 to 9, wherein the PAG comprises one or more of ionic photoacid generators (PAGs), non-ionic PAGs, benzyl esters, imino esters, sulfonium based PAGs, and iodonium based PAGs.
11. The substrate arrangement according to any preceding clause, wherein the resist under-layer comprises polyvinylpyrrolidone (PVP).
12. The substrate arrangement according to any preceding clause, wherein the lithographic apparatus is an EUV system.
13. A lithographic apparatus comprising the substrate arrangement according to any of clauses 1 to 12.
14. The use of a substrate arrangement according to any of clauses 1 to 12 in a lithographic process.
15. A method of manufacturing a substrate arrangement, the method comprising: coating the surface of a substrate with a photosensitive resist under-layer; and providing a resist on the photosensitive resist under-layer; wherein the exposure threshold of the resist under-layer is lower than the exposure threshold of the resist.
16. The method according to clause 15, wherein the substrate arrangement is according to any of clauses 1 to 12.
17. A method comprising: projecting a patterned beam of radiation onto a substrate arrangement according to any of clauses 1 to 12 in an exposure process; and performing a development process on the substrate arrangement.
18. A method comprising using the method according to clause 17 in the manufacture of semiconductors by a lithographic apparatus.
19. A device manufactured according to the method of clause 18.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims and clauses set out below.

1. A substrate arrangement for use in a lithographic apparatus, the substrate arrangement comprising:
a resist;
a photosensitive resist under-layer; and
a substrate,
wherein an exposure threshold of the resist under-layer is lower than an exposure threshold of the resist.

2. The substrate arrangement according to claim 1, wherein the resist and the resist under-layer are both photosensitive to EUV radiation.

3. The substrate arrangement according to claim 1, wherein the resist under-layer is configured to become more hydrophilic in response to irradiation by EUV radiation.

4. The substrate arrangement according to claim 1, wherein, in response to irradiation by EUV radiation, the polarity of the resist under-layer is configured to increase in magnitude, decrease in magnitude or change in sign.

5. The substrate arrangement according to claim 1, wherein:
the resist under-layer comprises polymers, a thermal initiator and a photoacid generator (PAG); and
the polymers comprise both cross-linkable groups and protected groups.

6. The substrate arrangement according to claim 5, wherein the substantial part of the resist underlayer is the protected groups.

7. The substrate arrangement according to claim 5, wherein the thermal initiator is configured to cross-link the cross-linkable groups in response to the resist under-layer being baked.

8. The substrate arrangement according to claim 5, wherein the thermal initiator comprises one or more selected from: an acrylate group, a methacrylate group, an epoxy group, 1,1′-Azobis(cyclohexanecarbonitrile), 2,2′-Azobisisobutyronitrile (AIBN), Benzoyl peroxide2 Benzene, 2,2-Bis(tert-butylperoxy)butane, 1,1-Bis(tert-butylperoxy)cyclohexane, 2,5-Bis(tert-butylperoxy)-2,5-dimethylhexane, 2,5-Bis(tert-Butylperoxy)-2,5-dimethyl-3-hexyne, Bis(1-(tert-butylperoxy)-1-methylethyl)benzene, 1,1-Bis(tert-butylperoxy)-3,3,5-85 (dibutyl phthalate) trimethylcyclohexane, tert-Butyl hydroperoxide Benzene, tert-Butyl peracetate Benzene, tert-Butyl peroxide Benzene, tert-Butyl peroxybenzoate, tert-Butylperoxy isopropyl carbonate Cumene, Cyclohexanone peroxide, Dicumyl peroxide Benzene, and/or Lauroyl peroxide Benzene, 2,4-Pentanedione peroxide.

9. The substrate arrangement according to claim 5, wherein the protected groups comprise one or more selected from: of tert-butoxycarbonyl protected polyhydroxystyrene, adamanthoxyethyl protected poly hydroxy styrene, and/or t-butyl acrylate.

10. The substrate arrangement according to claim 5, wherein the PAG comprises one or more selected from: an ionic photoacid generator, a non-ionic PAG, a benzyl ester, an imino ester, a sulfonium based PAG, and/or an iodonium based PAG.

11. The substrate arrangement according to claim 1, wherein the resist under-layer comprises polyvinylpyrrolidone (PVP).

12. A method of manufacturing a substrate arrangement, the method comprising:
coating a surface of a substrate with a photosensitive resist under-layer; and
providing a resist on the photosensitive resist under-layer,
wherein an exposure threshold of the resist under-layer is lower than an exposure threshold of the resist.

13. (canceled)

14. A method comprising:
projecting a patterned beam of radiation onto a substrate arrangement according to claim 1 in an exposure process; and
performing a development process on the substrate arrangement.

15. A device manufactured according to the method of claim 14.

16. The method of claim 12, wherein the resist and the resist under-layer are both photosensitive to EUV radiation.

17. The method of claim 12, wherein the resist under-layer is configured to become more hydrophilic in response to irradiation by EUV radiation.

18. The method of claim 12, wherein:
the resist under-layer comprises polymers, a thermal initiator and a photoacid generator (PAG); and
the polymers comprise both cross-linkable groups and protected groups.

19. The method of claim 18, wherein the substantial part of the resist underlayer is the protected groups.

20. The method of claim 18, wherein the thermal initiator is configured to cross-link the cross-linkable groups in response to the resist under-layer being baked.

21. The method of claim 12, wherein the resist under-layer comprises polyvinylpyrrolidone (PVP).
